(19) United States
(12) Patent Application Publication
(10) Pub. No.: US 2026/0164748 A1
(43) Pub. Date: Jun. 11, 2026

(54) SEMICONDUCTOR DEVICE

(71) Applicant: Samsung Electronics Co., Ltd., Suwon-si (KR)

(72) Inventors: Hakseon KIM, Suwon-si (KR); Seongpil CHANG, Suwon-si (KR); Sejun PARK, Suwon-si (KR); Sea Hoon LEE, Suwon-si (KR)

(73) Assignee: Samsung Electronics Co., Ltd., Suwon-si (KR)

(21) Appl. No.: 19/389,432

(22) Filed: Nov. 14, 2025

(30) Foreign Application Priority Data
Dec. 10, 2024 (KR) 10-2024-0182885

(51) Int. Cl. H10D 64/00; H10D 64/23

(52) U.S. Cl. CPC H10D 64/112; H10D 64/258

(57) ABSTRACT

A semiconductor device includes a substrate, a gate electrode, a first source/drain region, a second source/drain region spaced apart from the first source/drain region having the gate electrode therebetween in a first direction, a first source/drain contact, a second source/drain contact, a gate contact connected with the gate electrode, a first field plate connected with the gate contact, and includes a first region overlapping with the first source/drain region when viewed in a second direction, and a second field plate connected with the first field plate and includes a second region overlapping with the second source/drain region when viewed in the second direction. A distance between the second source/drain region and the second region in the second direction is greater than a distance between the first source/drain region and the first region in the second direction.

### CROSS-REFERENCE TO RELATED APPLICATION

This U.S. non-provisional application claims priority under 35 U.S.C. § 119 to Korean Patent Application No. 10-2024-0182885, filed on Dec. 10, 2024, in the Korean Intellectual Property Office, the disclosure of which is incorporated herein by reference in its entirety.

### BACKGROUND

Example embodiments relate to a semiconductor device.

A high voltage (HV) device may include a field plate positioned on a source/drain region or a gate electrode for ion boosting, which may improve or increase the intensity of the current (I_{DS}) flowing between a source region and a drain region.

The field plate can provide an ion boosting effect by improving or increasing the electric field in the source/drain region. When an increased electric field is concentrated in a given region, the breakdown voltage (BV) may decrease and current leakage may occur when the device is turned off.

### SUMMARY

Example embodiments are directed to a semiconductor device that provides ion boosting effect reduces the decrease in the breakdown voltage (BV) and the occurrence of current leakage, by reducing the electric field from being concentrated in a specific region.

The technical tasks to be achieved by the example embodiments are not limited to the technical tasks described above, and other technical tasks may be inferred from the following example embodiments by those skilled in the art.

According to some example embodiments, a semiconductor device includes a substrate, a gate electrode on the substrate, a first source/drain region in the substrate, a second source/drain region in the substrate and spaced apart from the first source/drain region, the gate electrode being between the first source/drain region and the second source/drain region in a first direction parallel to a surface of the substrate, a first source/drain contact connected with the first source/drain region, a second source/drain contact connected with the second source/drain region, a gate contact connected with the gate electrode, a first field plate connected with the gate contact, and including a first region at least partially overlapping with the first source/drain region when viewed in a second direction perpendicular to the surface of the substrate, and a second field plate connected with the first field plate, and including a second region at least partially overlapping with the second source/drain region when viewed in the second direction. A distance between the second source/drain region and the second region in the second direction is greater than a distance between the first source/drain region and the first region in the second direction.

According to some example embodiments, a semiconductor device includes a substrate, an active region that includes a first source/drain region in the substrate and a second source/drain region that is spaced apart from the first source/drain region in a first direction parallel to a surface of the substrate, the active region extending in the first direction, a field region that does not overlap with the active region when viewed in a second direction perpendicular to the surface of the substrate, a gate electrode between the first source/drain region and the second source/drain region on the substrate, the gate electrode extending in a third direction parallel to the surface of the substrate and intersecting with the first direction, a first source/drain contact connected to the first source/drain region, a second source/drain contact connected to the second source/drain region, a gate contact connected to the gate electrode, a first field plate connected to the gate contact, and including a first region at least partially overlapping with the first source/drain region when viewed in the second direction, and a second field plate connected to the first field plate and including a second region at least partially overlapping with the second source/drain region when viewed in the second direction. A distance between the second source/drain region and the second region in the second direction is greater than a distance between the first source/drain region and the first region in the second direction.

According to some example embodiments, a semiconductor device includes a substrate, an active region that includes a first source/drain region in the substrate and a second source/drain region spaced apart from the first source/drain region in a first direction parallel to a surface of the substrate, the active region extending in the first direction, a field region that does not overlap with the active region when viewed in a second direction perpendicular to the surface of the substrate, a gate electrode between the first source/drain region and the second source/drain region on the substrate, the gate electrode extending in a third direction parallel to the surface of the substrate and intersecting with the first direction, a first source/drain contact connected to the first source/drain region, a second source/drain contact connected to the second source/drain region, a gate contact connected to the gate electrode, a first field plate connected to the gate contact, and including a first region at least partially overlapping with the first source/drain region and a third region at least partially overlapping with the gate electrode and connected with the first region when viewed in the second direction, and a second field plate connected to the first field plate, and including a second region at least partially overlapping with the second source/drain region and a fourth region at least partially overlapping with the gate electrode and connected with the second region when viewed in the second direction. The third region includes a 3-1 region extending in a direction same as a direction in which the first region extends with respect to the gate contact, and a 3-2 region extending in a direction opposite to the direction in which the 3-1 region extends, the fourth region includes a 4-1 region extending in a direction same as a direction in which the second region extends with respect to the gate contact, and a 4-2 region extending in a direction opposite to the direction in which the 4-1 region extends, a distance between the second source/drain region and the second region in the second direction is greater than a distance between the first source/drain region and the first region in the second direction, and a distance between the first source/drain contact and the gate electrode in the first direction is greater than a distance between the second source/drain contact and the gate electrode in the first direction.

According to some example embodiments, a method of manufacturing a semiconductor device includes forming a gate electrode on a substrate, forming a first source/drain region in the substrate, forming a second source/drain region in the substrate and spaced apart from the first source/drain region, the gate electrode being between the first source/drain region and the second source/drain region in a first direction parallel to a surface of the substrate, forming a first source/drain contact connected with the first source/drain region, forming a second source/drain contact connected with the second source/drain region, forming a gate contact connected with the gate electrode, forming a first field plate connected with the gate contact, the first field plate including a first region at least partially overlapping with the first source/drain region when viewed in a second direction perpendicular to the surface of the substrate, and forming a second field plate connected with the first field plate such that a distance between the second source/drain region and a second region of the second field plate in the second direction is greater than a distance between the first source/drain region and the first region in the second direction, the second region at least partially overlapping with the second source/drain region when viewed in the second direction.

According to some example embodiments, the forming the first source/drain contact includes forming the first source/drain contact having a first distance between the first source/drain contact and the gate electrode in the first direction, the forming the second source/drain contact includes forming the second source/drain contact having a second distance between the second source/drain contact and the gate electrode in the first direction, and the first distance and the second distance are different. According to some example embodiments, the distance between the first source/drain contact and the gate electrode in the first direction is greater than the distance between the second source/drain contact and the gate electrode in the first direction. According to some example embodiments, the forming the first source/drain contact includes forming the first source/drain contact having a first distance between the first source/drain contact and the gate electrode in the first direction, the forming the second source/drain contact includes forming the second source/drain contact having a second distance between the second source/drain contact and the gate electrode in the first direction, and the first distance and the second distance are same. According to some example embodiments, the forming the first field plate further includes forming the first field plate having a third region at least partially overlapping with the gate electrode when viewed in the second direction and connected with the first region.

Additional aspects of example embodiments will be set forth in part in the description which follows and, in part, will be apparent from the description, or may be learned by practice of the disclosure.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIG. 1 is a layout drawing of a semiconductor device according to some example embodiments.

FIG. 2 illustrates a cross-section taken along line A-A′ of a semiconductor device of FIG. 1, according to some example embodiments.

FIG. 3 illustrates a cross-section taken along line A-A′ of a semiconductor device of FIG. 1, according to some example embodiments.

FIG. 4 illustrates a cross-section taken along line A-A′ of a semiconductor device of FIG. 1, according to some example embodiments.

FIG. 5 illustrates a cross-section taken along line A-A′ of a semiconductor device of FIG. 1, according to some example embodiments.

FIG. 6 illustrates a cross-section taken along line A-A′ of a semiconductor device of FIG. 1, according to some example embodiments.

FIG. 7 is a layout of a semiconductor device including a first field plate in a mesh form according to some example embodiments.

FIG. 8 is a layout of a semiconductor device including a second field plate in the mesh form according to some example embodiments.

FIG. 9 is a layout of a semiconductor device including a first field plate and a second field plate in the mesh form according to some example embodiments.

FIG. 10 is a layout of a semiconductor device including a first field plate in a planar form according to some example embodiments.

FIG. 11 is a layout of a semiconductor device including a first field plate in the planar form and a second field plate in the mesh form according to some example embodiments.

FIG. 12 is a layout of a semiconductor device including a second field plate in the planar form according to some example embodiments.

FIG. 13 is a layout of a semiconductor device including a first field plate in the mesh form and a second field plate in the planar form according to some example embodiments.

FIG. 14 is a layout of a semiconductor device including a first field plate and a second field plate in the planar form according to some example embodiments.

FIG. 15 is a layout of a semiconductor device including a first field plate and a second field plate in the mesh form and the first field plate and the second field plate are disposed only on an active region, according to some example embodiments.

FIG. 16 is a layout of a semiconductor device including a first field plate and a second field plate in the planar form and the first field plate and the second field plate are disposed only on an active region, according to some example embodiments.

### DETAILED DESCRIPTION

Prior to the detailed description of the present disclosure, terms or words used in the specification and claims may not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only the most preferred embodiments of the present disclosure, and do not necessarily represent the entire technical idea of the present disclosure. Accordingly, at the time of filing the present disclosure, there may be various equivalents and modifications that can replace them.

The same reference numeral or sign shown in each drawing attached to the specification may represent parts or components that perform substantially the same function. For convenience of description and understanding, different embodiments may be described using the same reference numerals or symbols. In other words, even if a component or an element having the same reference numeral is shown in multiple drawings, the multiple drawings may not all represent one example embodiment.

In the present disclosure, when an element is described as being “directly on,” “adjacent to” or “in contact with” another element, the element may be understood as being in direct contact with or connected to the another element, and it may be understood that there is no other element between the two.

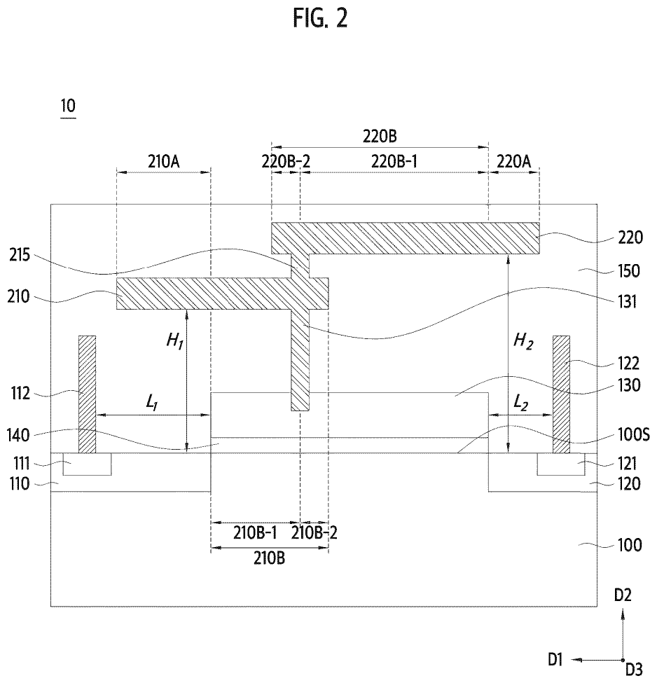

Further, in the present disclosure, when an element is described as being “on an upper surface” or “on an upper portion” of another element, the element may be understood as existing above the vertical direction, for example, as being above the +D2 direction in the drawing (FIG. 2), and the two elements may be in direct contact or connected, but it may also be understood that another element exists between the two. The same is applied even when an element is described as being “above/over” another element in the present disclosure.

Further, in the present disclosure, when an element is described as being “on a lower portion” or “on a bottom surface” of another element, the element may be understood as existing below based on the vertical direction, for example, being further below based on the −D2 direction in the drawing (FIG. 2), and the two elements may be in direct contact or connected, but it may also be understood that another element exists between the two. The same is applied even when an element is described as being “underneath/beneath” another element.

Other similar expressions describing the positional relationship between elements can also be interpreted similarly as above.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as upper side, upper surface, lower side, lower surface, side, a front side, and a back side are expressed based on the direction shown in the drawing. If the direction of the object changes, it may be expressed differently.

Further, in the specification and claims, terms including ordinal numbers such as “first,” “second,” etc. may be used to distinguish between components or elements. These ordinal numbers are used to distinguish identical or similar components from each other, and the meaning of the terms should not be interpreted limitedly due to the use of such ordinal numbers. For example, components or elements combined with these ordinal numbers should not be interpreted as having a limited order of use or arrangement based on the number. If necessary, each ordinal number may be used interchangeably.

The properties described in the present disclosure may be measured in a room temperature and pressure environment unless specifically limited. In the present disclosure, as the natural temperature without any artificial manipulation, the room temperature/ambient temperature can be 10° C. to 30° C., 20° C. to 28° C. or 22° C. to 26° C. In some example embodiments, the room temperature can be 25° C. In some example embodiments, as a natural pressure without any artificial manipulation, the pressure may be between 700 mmHg and 800 mmHg or between 720 mmHg and 780 mmHg, and in one example embodiment may be 760 mmHg.

The properties described in the present disclosure may have units according to the international system of units unless otherwise specified.

Hereinafter, example embodiments according to the technical idea of the present disclosure are described with reference to the attached drawings. Further, for brevity, existing elements, structures or layers of a semiconductor device according to an example may be described in detail herein, or not.

The drawings illustrated in the present disclosure are according to mere example embodiments, and the ratio of the width, the length, and the height (or the thickness) of each element is for detailed descriptions for the example embodiments, and thus the ratio may differ from reality. Further, in the coordinate system illustrated in the drawings, each axis may be perpendicular to each other, and the direction the arrow points may be the + direction, and the direction opposite to the direction indicated by the arrow (rotated by 180 degrees) may be the − direction.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

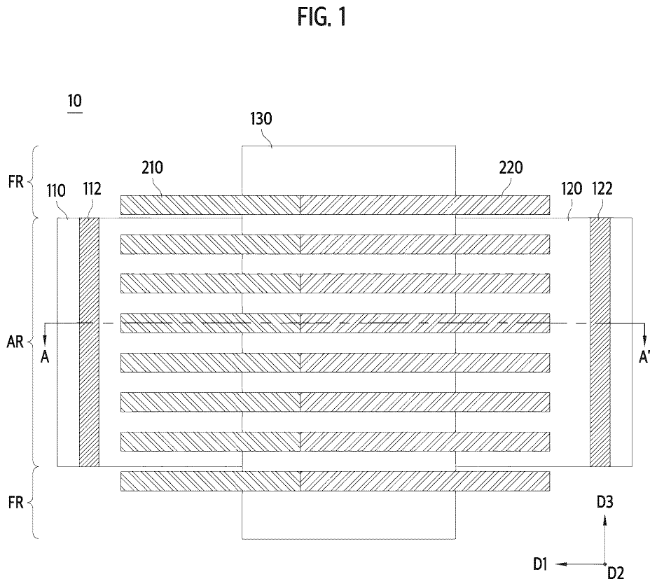

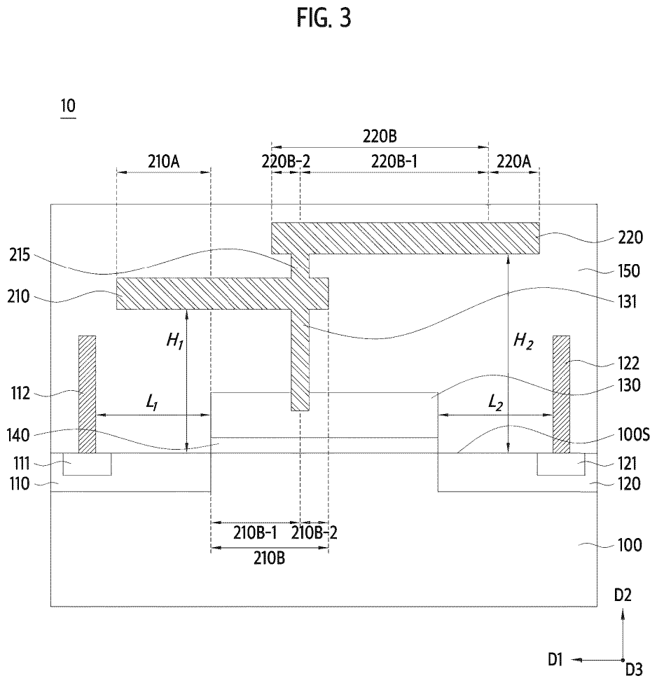

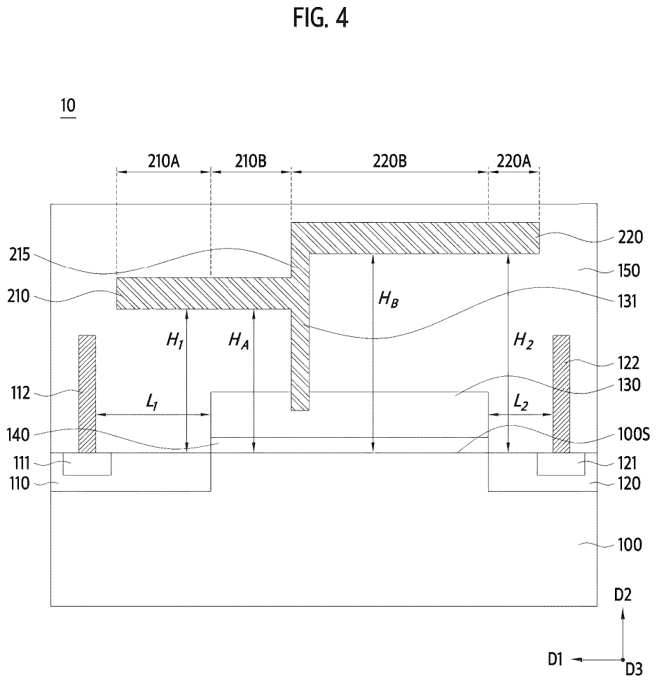

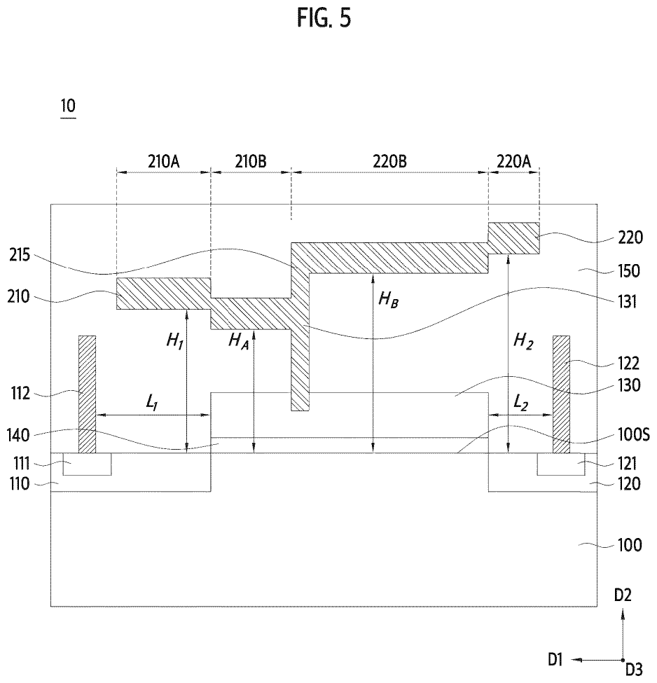

FIG. 1 is a layout drawing of a semiconductor device 10 according to some example embodiments. FIG. 2 illustrates a cross-section taken along line A-A′ of the semiconductor device 10 of FIG. 1, according to some example embodiments. FIG. 3 illustrates a cross-section taken along line A-A′ of the semiconductor device 10 of FIG. 1, according to some example embodiments. FIG. 4 illustrates a cross-section taken along line A-A′ of the semiconductor device 10 of FIG. 1, according to some example embodiments. FIG. 5 illustrates a cross-section taken along line A-A′ of the semiconductor device 10 of FIG. 1, according to some example embodiments.

In some example embodiments, the first direction D1 may be a direction parallel to a surface 100S of a substrate 100. The second direction D2 may be a direction perpendicular to the surface 100S of the substrate 100. The second direction D2 may intersect the first direction D1, for example. The third direction D3 may be a direction parallel to the surface 100S of the substrate 100 while intersecting the first direction D1. The third direction D3 may intersect, for example, the first direction D1 and the second direction D2. For example, the intersection angle of the first direction D1 and the second direction D2 may be 90 degrees, the intersection angle between the second direction D2 and the third direction D3 may be 90 degrees, and the intersection angle between the first direction D1 and the third direction D3 may be 90 degrees.

In some example embodiments, the insulating material may have an electrical conductivity of 10⁻⁶ S/m or less. In some example embodiments, the electrical conductivity is not specifically limited, but may be measured, for example, by ASTM E 1004. For example, the insulating material may include at least of silicon oxide, silicon-germanium oxide, germanium oxide, silicon oxynitride, silicon nitride, a high-k material having a dielectric constant higher than silicon oxide, or a low-k material having a dielectric constant lower than silicon oxide. The high-k material may include one or more of, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. However, the high-k material is not limited thereto. The low-k material may include one or more of, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels and mesoporous silica. However, the low-k material is not limited thereto.

In some example embodiments, the conductive material may have an electrical conductivity greater than 10⁶ S/m. For example, the conductive material may include at least one of a metal, a metal alloy, a conductive metal nitride, a metal silicide, a doped semiconductor material, a conductive metal oxide, and a conductive metal oxynitride. For example, the conductive material may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), and vanadium (V). However, the conductive material is not limited thereto. The conductive metal oxide and conductive metal oxynitride may include oxidized forms of the above-described substances, but the conductive metal oxide and conductive metal oxynitride are not limited thereto.

In some example embodiments, the semiconductor device 10 may include the substrate 100, a first source/drain region 110, a first source/drain contact 112, a second source/drain region 120, a second source/drain contact 122, a gate electrode 130, a gate contact 131, a first field plate 210 and a second field plate 220.

In some example embodiments, the substrate 100 may include silicon (Si). In some example embodiments, the substrate 100 may include a group IV-IV compound semiconductor or a group III-V compound semiconductor, and more specifically, may include a binary compound, a ternary compound, or a quaternary compound including at least two of carbon (C), silicon (Si), germanium (Ge) and tin (Sn), and compounds in which group IV elements are doped into binary compounds. In some example embodiments, the group III-V compound semiconductor may be, for example, a binary compound, a ternary compound, or a quaternary compound formed by combining at least one of aluminum (Al), gallium (Ga) and indium (In) which are the group III elements and one of phosphorus (P), arsenic (As) and antimony (Sb) which are the group V elements.

In some example embodiments, the semiconductor device 10 may include an active region AR and a field region FR. The active region AR may extend in the first direction D1. A plurality of active regions AR may be disposed, and adjacent active regions AR may be separated from each other. For example, the adjacent active regions AR may be separated from each other in the third direction D3. The field region FR may not overlap with the active regions AR when viewed in the second direction D2. A plurality of field regions FR may be disposed, and the field regions FR may be disposed between the active regions AR that are spaced apart from each other. The field regions FR may form boundaries with the adjacent active regions AR.

In some example embodiments, the field region FR may be defined by a trench, but the field region FR is not limited thereto. It is apparent that a person skilled in the art of the present disclosure may distinguish which part is the field region FR and which part is the active region AR. The field region FR may include the shallow trench isolation (STI) structure, but is not limited thereto.

In some example embodiments, the semiconductor device 10 may include a device separating film (not illustrated) disposed around the active region AR. The field region FR may be disposed in a region between the adjacent active regions AR in a device separating film. In some example embodiments, the active region AR may include the first source/drain region 110 and the second source/drain region 120.

In some example embodiments, the first source/drain region 110 and the second source/drain region 120 may be positioned within the substrate 100. The second source/drain region 120 may be separated from the first source/drain region 110 with the gate electrode 130 interposed therebetween, in the first direction D1.

In some example embodiments, each of the first source/drain region 110 and the second source/drain region 120 may independently include silicon (Si). In some example embodiments, each of the first source/drain region 110 and the second source/drain region 120 may independently include a group IV-IV compound semiconductor or a group III-V compound semiconductor. Each of the first source/drain region 110 and the second source/drain region 120 may independently include a binary compound, a ternary compound or a quaternary compound which includes at least two of carbon (C), silicon (Si), germanium (Ge) and tin (Sn). The first source/drain region 110 and the second source/drain region 120 may include the same material as the substrate 100.

In some example embodiments, each of the first source/drain region 110 and the second source/drain region 120 may independently include impurities. The impurities may include an n-type dopant including one or more of phosphorus (P), arsenic (As), antimony (Sb) and bismuth (Bi). In some example embodiments, the impurities may include a p-type dopant including at least one of boron (B) and gallium (Ga). Each of the first source/drain region 110 and the second source/drain region 120 may independently include the n-type dopant or the p-type dopant. The first source/drain region 110 and the second source/drain region 120 may include the same dopant.

In some example embodiments, the first source/drain contact 112 may be connected to the first source/drain region 110. The first source/drain contact 112 may be extended in the second direction D2. The first source/drain region 110 may include a first source/drain contact region 111 in contact with the first source/drain contact 112. When impurities are included in the first source/drain region 110, the first source/drain contact region 111 may have a lower concentration of impurities than the other region of the first source/drain region 110. When the concentration of impurities in the first source/drain contact region 111 is relatively low, the durability of the semiconductor device 10 may be improved due to the HV driving. In some example embodiments, the first source/drain contact 112 may be extended in the third direction D3. The first source/drain contact 112 may be placed or arranged on the active region AR. The first source/drain contact 112 may include one or more of polysilicon and conductive materials.

In some example embodiments, the second source/drain contact 122 may be connected to the second source/drain region 120. The second source/drain contact 122 may be extended in the second direction D2. The second source/drain contact 122 may be parallel to the first source/drain contact 112. The second source/drain region 120 may include a second source/drain contact region 121 in contact with the second source/drain contact 122. When impurities are included in the second source/drain region 120, the second source/drain contact region 121 may have a lower concentration of impurities than the other regions in the second source/drain region 120. When the concentration of impurities in the second source/drain contact region 121 is relatively low, the durability of the semiconductor device 10 may be improved due to the HV driving. In some example embodiments, the second source/drain contact 122 may extend in the third direction D3. The second source/drain contact 122 may be placed on the active region AR. The second source/drain contact 122 may include one or more of polysilicon and conductive materials.

In some example embodiments, the gate electrode 130 may be disposed on the substrate 100. The gate electrode 130 may be placed between the first source/drain region 110 and the second source/drain region 120 on the substrate 100. The gate electrode 130 may be extended, for example, in the third direction D3. A plurality of gate electrodes 130 may be disposed, and adjacent gate electrodes 130 may be spaced apart from each other. For example, the adjacent gate electrodes 130 may be spaced apart from each other in the first direction D1. The gate electrode 130 may include one or more of polysilicon and conductive materials. In some example embodiments, when viewed in the second direction D2, the gate electrode 130 may not overlap the first source/drain region 110 and the second source/drain region 120.

In some example embodiments, the distance L₁ between the first source/drain contact 112 and the gate electrode 130 in the first direction D1 may be different from the distance L₂ between the second source/drain contact 122 and the gate electrode 130 in the first direction D1 (see FIG. 2). In other words, the semiconductor device 10 may be an asymmetric device. Here, the distance L₁ being different from the distance L₂ may indicate that the difference between the distance L₁ between the first source/drain contact 112 and the gate electrode 130 in the first direction D1 and the distance L₂ between the second source/drain contact 122 and the gate electrode 130 in the first direction D1 is more than 5%, based on the distance L₁ between the first source/drain contact 112 and the gate electrode 130 in the first direction D1.

In some example embodiments, the distance L₁ between the first source/drain contact 112 and the gate electrode 130 in the first direction D1 may be equal to the distance L₂ between the second source/drain contact 122 and the gate electrode 130 in the first direction D1. Here, the distance L₁ being equal to the distance L₂ may indicate that the distance L₁ and the distance L₂ being substantially identical (see FIG. 3). Further, here, the distance L₁ and the distance L₂ being substantially identical may indicate that the difference between the distance L₁ between the first source/drain contact 112 and the gate electrode 130 in the first direction D1 and the distance L₂ between the second source/drain contact 122 and the gate electrode 130 in the first direction D1 is 5% or less than 5%, based on the distance L₁ between the first source/drain contact 112 and the gate electrode 130 in the first direction D1.

In some example embodiments, the gate contact 131 may be connected to the gate electrode 130. The gate contact 131 may be electrically connected to the gate electrode 130. The gate contact 131 may be extended in the second direction D2. The gate contact 131 may include one or more of polysilicon and conductive materials.

In some example embodiments, the first field plate 210 may be connected to the gate contact 131. The first field plate 210 may be electrically connected to the gate contact 131. When viewed in the second direction D2, the first field plate 210 may include a first region 210A overlapping the first source/drain region 110. When viewed in the second direction D2, the first field plate 210 may not overlap the first source/drain contact 112.

In some example embodiments, there may be a plurality of first field plates 210. Each of the plurality of first field plates 210 may be extended in the first direction D1, and the plurality of first field plates 210 may be spaced apart from each other in the third direction D3.

In some example embodiments, the second field plate 220 may be electrically connected to the gate contact 131. The second field plate 220 may be connected to the first field plate 210. When viewed in the second direction D2, the second field plate 220 may include a second region 220A overlapping the second source/drain region 120. When viewed in the second direction D2, the second field plate 220 may not overlap with the second source/drain contact 122.

In some example embodiments, there may be a plurality of second field plates 220. Each of the plurality of second field plates 220 may be extended in the first direction D1, and the plurality of second field plates 220 may be spaced apart from each other in the third direction D3.

In some example embodiments, the distance H₂ between the second source/drain region 120 and the second field plate 220 in the second direction D2 may be greater than the distance H₁ between the first source/drain region 110 and the first field plate 210 in the second direction D2. This reduces or limits the electric field from being concentrated (e.g., excessively concentrated) in a specific region of the semiconductor device 10, and the decrease in the BV and the occurrence of current leakage may be reduced while the ion boosting effect may be obtained or observed.

In some example embodiments, the distance H₂ between the second source/drain region 120 and the second region 220A in the second direction D2 may be greater than the distance H₁ between the first source/drain region 110 and the first region 210A in the second direction D2. This reduces or limits the electric field from being concentrated (e.g., excessively concentrated) in a specific region of the semiconductor device 10, and the decrease in the BV and the occurrence of current leakage may be reduced while the ion boosting effect may be obtained or observed.

According to some example embodiments, by reducing the electric field from being concentrated in a specific region, it is possible to provide a semiconductor device that provides the ion boosting effect and reduces the BV and the occurrence of current leakage.

In some example embodiments, the distance L₁ between the first source/drain contact 112 and the gate electrode 130 in the first direction D1 may be greater than the distance L₂ between the second source/drain contact 122 and the gate electrode 130 in the first direction D1. The electric field may not be concentrated (e.g., excessively concentrated) in a specific region of the semiconductor device 10 by the distance H₂ between the second source/drain region 120 and the second region 220A in the second direction D2 being greater than the distance H₁ between the first source/drain region 110 and the first region 210A in the second direction D2.

In some example embodiments, when the semiconductor device 10 is an asymmetric device, the electric field may not be concentrated in a specific region of the semiconductor device 10 by varying the distance (the distance H₁ and the distance H₂) between the field plate (the first field plate 210 and the second field plate 220) and the source/drain region (the first source/drain region 110 and the second source/drain region 120) in the second direction D2.

In some example embodiments, when viewed in the second direction D2, the first field plate 210 may include a third region 210B that overlaps the gate electrode 130 and is connected to the first region 210A. The third region 210B may be electrically connected to the first region 210A.

In some example embodiments, the distance H_{A} between the substrate 100 and the third region 210B in the second direction D2 may be substantially identical to the distance H₁ between the first source/drain region 110 and the first region 210A in the second direction D2. Here, the distance H_{A} being substantially identical to the distance H₁ may indicate that the difference between the distance H_{A} between the substrate 100 and the third region 210B in the second direction D2 and the distance H₁ between the first source/drain region 110 and the first region 210A in the second direction D2 is 5% or less than 5%, based on the distance H1 between the first source/drain region 110 and the first region 210A in the second direction D2.

In some example embodiments, the distance H_{A} between the substrate 100 and the third region 210B in the second direction D2 may be different from the distance H₁ between the first source/drain region 110 and the first region 210A in the second direction D2. Here, the distance H_{A} being different from the distance H₁ may indicate that the difference between the distance H_{A} between the substrate 100 and the third region 210B in the second direction D2 and the distance H₁ between the first source/drain region 110 and the first region 210A in the second direction D2 is more than 5%, based on the distance H₁ between the first source/drain region 110 and the first region 210A in the second direction D2. In some example embodiments, the distance H_{A} between the substrate 100 and the third region 210B in the second direction D2 may be smaller than the distance H₁ between the first source/drain region 110 and the first region 210A in the second direction D2. In some example embodiments, the distance H_{A} between substrate 100 and the third region 210B in the second direction D2 may be greater than the distance H₁ between the first source/drain region 110 and the first region 210A in the second direction D2.

In some example embodiments, the third region 210B may include a 3-1 region 210B-1 that is disposed to extend in the direction similar to or same as the direction (for example, +D1) in which the first region 210A is extended with respect to the gate contact 131, and a 3-2 region 210B-2 that is disposed to extend in a direction (for example, −D1) that is opposite to the direction (for example, +D1) in which the 3-1 region 210B-1 is extended.

In some example embodiments, when viewed in the second direction D2, the second field plate 220 may include a fourth region 220B that overlaps at least partly with the gate electrode 130 and is connected to the second region 220A. The fourth region 220B may be electrically connected to the second region 220A.

In some example embodiments, the distance H_{B} between the substrate 100 and the fourth region 220B in the second direction D2 may be substantially equal to the distance H₂ between the second source/drain region 120 and the second region 220A in the second direction D2. Here, the distance H_{B} being substantially equal to the distance H₂ may indicate that the difference between the distance H_{B} between the substrate 100 and the fourth region 220B in the second direction D2 and the distance H₂ between the second source/drain region 120 and the second region 220A in the second direction D2 is less than 5%, based on the distance H₁ between the second source/drain region 120 and the second region 220A in the second direction D2.

In some example embodiments, the distance H_{B} between the substrate 100 and the fourth region 220B in the second direction D2 may be different from the distance H₂ between the second source/drain region 120 and the second region 220A in the second direction D2. Here, the distance H_{B} being different from the distance H₂ may indicate that the difference between the distance H_{B} between the substrate 100 and the fourth region 220B in the second direction D2 and the distance H₂ between the second source/drain region 120 and the second region 220A in the second direction D2 is more than 5%, based on the distance H₂ between the second source/drain region 120 and the second region 220A in the second direction D2. In some example embodiments, the distance H_{B} between the substrate 100 and the fourth region 220B in the second direction D2 may be smaller than the distance H₁ between the second source/drain region 120 and the second region 220A in the second direction D2. In some example embodiments, the distance H_{B} between the substrate 100 and the fourth region 220B in the second direction may be greater than the distance H₂ between the second source/drain region 120 and the second region 220A in the second direction D2.

In some example embodiments, the fourth region 220B may include a 4-1 region 220B-1 that is disposed to extend in the direction similar to the direction (for example, −D1) in which the second region 220A is extended based on the gate contact 131, and a 4-2 region 220B-2 that is disposed to extend in the direction (for example, +D1) that is opposite to the direction (for example, −D1) in which the 4-1 region 220B-1 is extended.

In some example embodiments, the semiconductor device 10 may include a connecting contact 215 connected to the first field plate 210 and the second field plate 220. The first field plate 210 and the second field plate 220 may be arranged spaced apart from each other in the second direction D2. The connecting contact 215 may be positioned in the space between the first field plate 210 and the second field plate 220. The connecting contact 215 may include one or more of polysilicon and conductive materials. When viewed in the second direction D2, the connecting contact 215 may overlap at least a portion of the gate contact 131.

In some example embodiments, the semiconductor device 10 may include a gate insulating film 140 disposed between the gate electrode 130 and the substrate 100. The gate insulating film 140 may include an insulating material. When viewed in the second direction D2, the gate electrode 130 and the gate insulating film 140 may at least partially overlap each other. When viewed in the second direction D2, the gate insulating film 140 may not overlap with the first source/drain region 110 and the second source/drain region 120.

In some example embodiments, the semiconductor device 10 may include an insulating film 150 surrounding the first field plate 210 and the second field plate 220. The insulating film 150 may contain an insulating material. The insulating film 150 may be placed on the substrate 100. The insulating film 150 may surround the gate electrode 130. The insulating film 150 may surround the first source/drain contact 112 and the second source/drain contact 122.

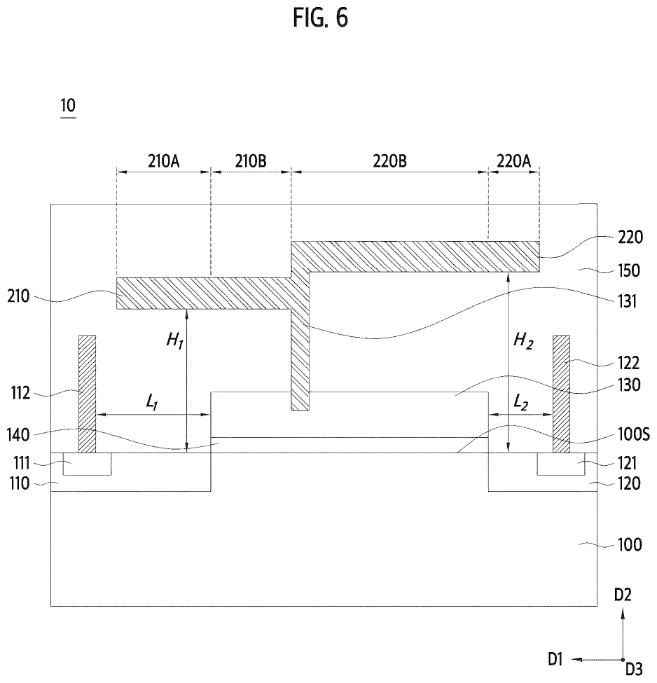

FIG. 6 illustrates a cross-section taken along line A-A′ of the semiconductor device 10 of FIG. 1, according to some example embodiments. The semiconductor device 10 of FIG. 6 may be same as or similar in some respects to the semiconductor device 10 of FIGS. 1-5, and therefore may be best understood with reference thereto where like numerals indicate like elements not described again in detail.

In some example embodiments, the first field plate 210 and the second field plate 220 may be in contact with each other in the second direction D2. In other words, the first field plate 210 and the second field plate 220 may be in contact without the connecting contact 215 described above, in the second direction D2.

In some example embodiments, when viewed in the first direction D1, the first field plate 210 and the second field plate 220 may not overlap each other. In some example embodiments, when viewed in the first direction D1, the first field plate 210 and the second field plate 220 may overlap at least in a region.

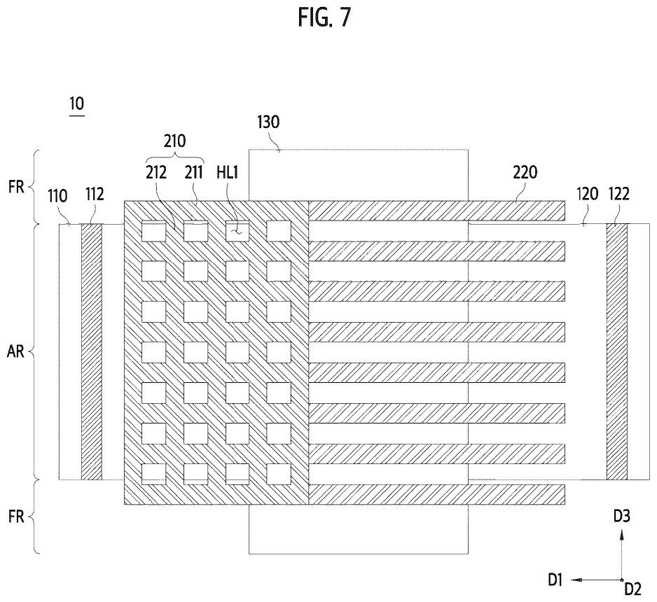

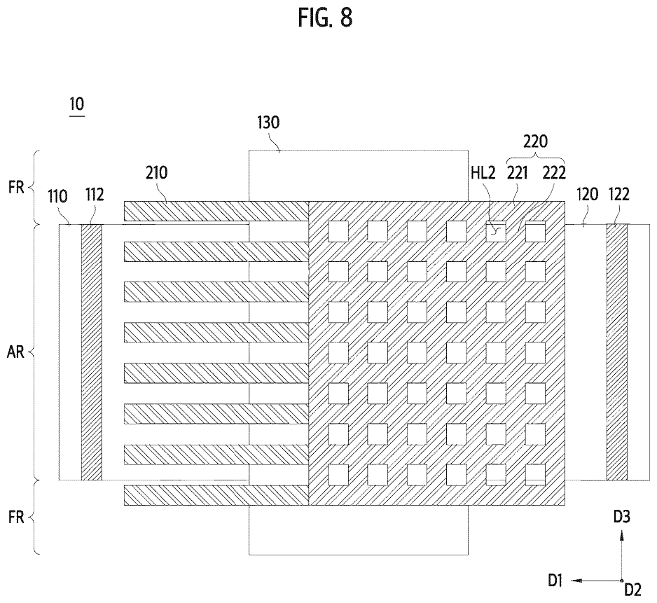

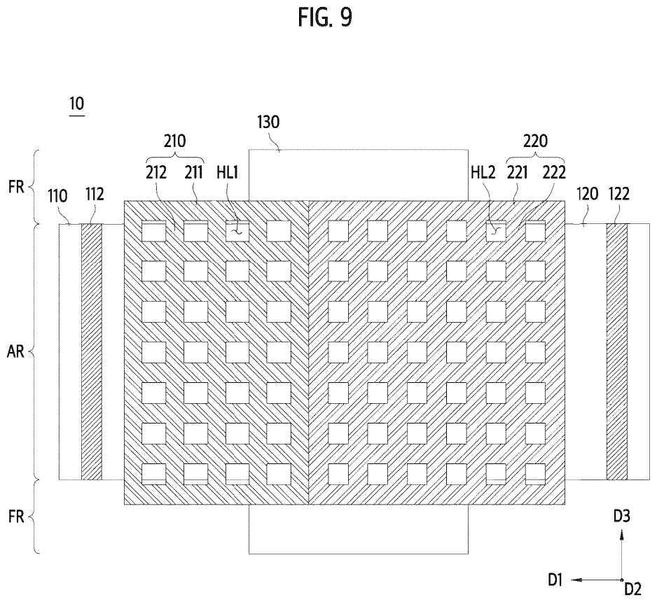

FIG. 7 is a layout of the semiconductor device 10 including the first field plate 210 in the mesh form according to some example embodiments. FIG. 8 is a layout of the semiconductor device 10 including the second field plate 220 in the mesh form according to some example embodiments. FIG. 9 is a layout of the semiconductor device 10 including the first field plate 210 and the second field plate 220 in the mesh form according to some example embodiments. The semiconductor device 10 of FIGS. 7-9 may be same as or similar in some respects to the semiconductor device 10 of FIGS. 1-6, and therefore may be best understood with reference thereto where like numerals indicate like elements not described again in detail.

In some example embodiments, the gate contact 131 may extend in the second direction D2 and the third direction D3. When viewed in the second direction D2, in some regions, the gate contact 131 may overlap with a portion of the first field plate 210 and a portion of the second field plate 220.

In some example embodiments, when viewed in the second direction D2, at least a portion of at least one of the first field plate 210 and the second field plate 220 may overlap with the active region AR. When viewed in the second direction D2, a region of at least one of the first field plate 210 and the second field plate 220 may overlap with the active region AR, and another region of at least one of the first field plate 210 and the second field plate 220 may overlap with the field region FR.

In some example embodiments, when viewed in the second direction D2, with regard to at least one of the first field plate 210 and the second field plate 220, the area of the region overlapping the active region AR may be larger than the area of the region overlapping the field region FR.

In some example embodiments, the first field plate 210 may include one or more 1-1 field plates 211 extending in the first direction D1 and one or more 1-2 field plates 212 extending in the third direction D3. The first field plate 210 may include one or more first cross holes HL1 surrounded by the one or more 1-1 field plates 211 and the one or more 1-2 field plates 212. Through this, the semiconductor device 10 may include the first field plate 210 in the mesh form.

In some example embodiments, the first field plate 210 may include the plurality of 1-1 field plates 211 and the plurality of 1-2 field plates 212. The plurality of 1-1 field plates 211 may be spaced apart from each other in the third direction D3, and the plurality of 1-2 field plates 212 may be spaced apart from each other in the first direction D1.

In some example embodiments, the first field plate 210 may include the plurality of 1-1 field plates 211 and the plurality of 1-2 field plates 212 in order for the plurality of first cross holes HL1 to be included. At least some of the plurality of first cross holes HL1 may each be identical in size (for example, the distance in the first direction D1 and the distance in the third direction D3 may be identical when viewed in the second direction D2). The size of the first cross holes HL1 may vary depending on the spaced distance of the adjacent 1-1 field plates 211 among the plurality of 1-1 field plates 211 in the third direction D3. Further, the size of the first cross holes HL1 may vary depending on the spaced distance of the adjacent 1-2 field plates 212 among the plurality of 1-2 field plates 212 in the first direction D1.

In some example embodiments, the second field plate 220 may include one or more 2-1 field plates 221 extending in the first direction D1, and one or more 2-2 field plates 222 extending in the third direction D3. The second field plate 220 may include one or more second cross holes HL2 surrounded by the one or more 2-1 field plates 221 and the one or more 2-2 field plates 222. This allows the semiconductor device 10 to include the second field plate 220 in the mesh form.

In some example embodiments, the second field plate 220 may include the plurality of 2-1 field plates 221 and the plurality of 2-2 field plates 222. The plurality of 2-1 field plates 221 may be spaced part from each other in the third direction D3, and the plurality of 2-2 field plates 222 may be spaced apart from each other in the first direction D1.

In some example embodiments, the second field plate 220 may include the plurality of 2-1 field plates 221 and the plurality of 2-2 field plates 222 in order for the plurality of second cross holes HL2 to be included. At least some of the plurality of second cross holes HL2 may be of the same size (for example, the distance in the first direction D1 and the distance in the third direction D3 may be identical when viewed in the third direction D3). The size of the second cross holes HL2 may vary depending on the spaced distance of the adjacent 2-1 field plates 221 among the plurality of 2-1 field plates 221 in the third direction D3. Further, the size of the second cross holes HL2 may vary depending on the spaced distance of the adjacent 2-2 field plates 222 among the plurality of 2-2 field plates 222 in the first direction D1.

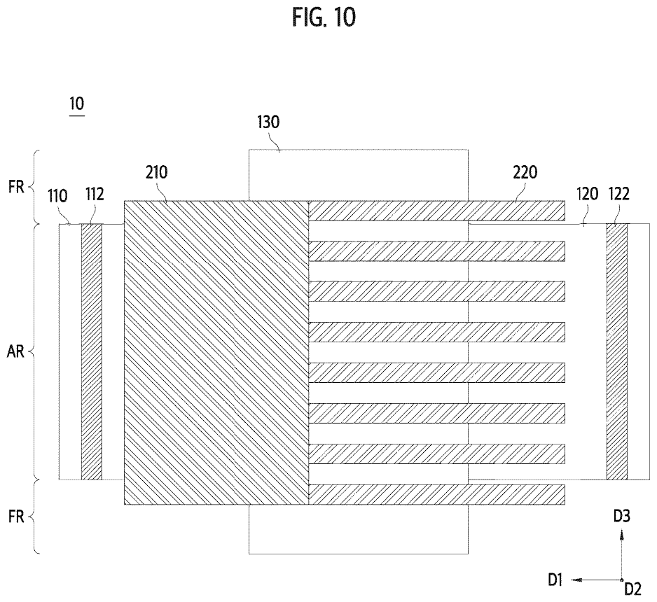

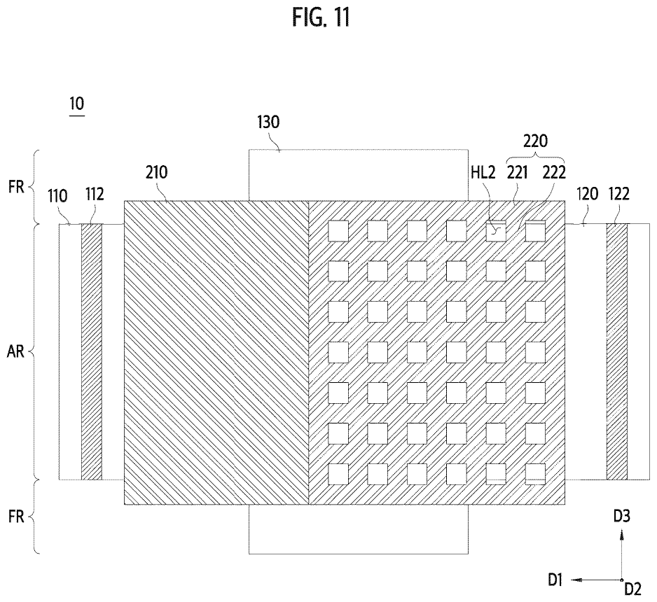

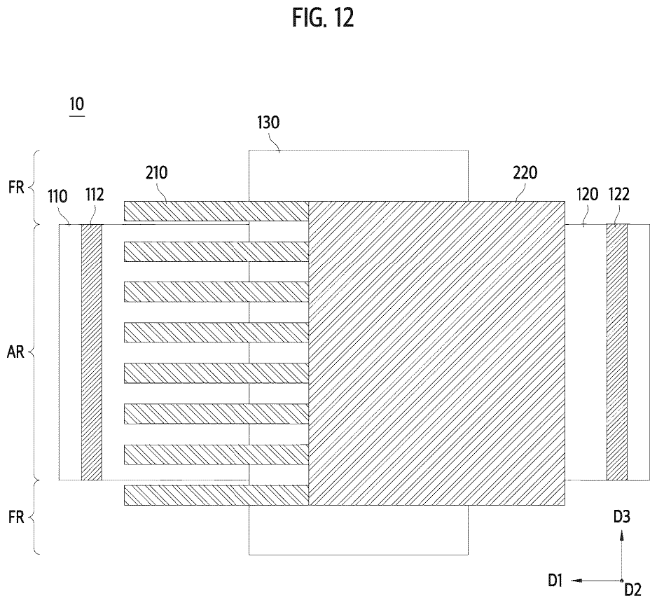

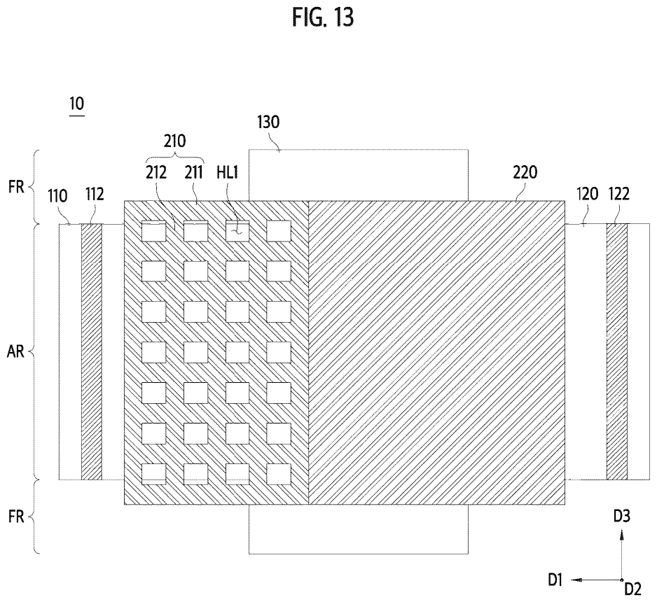

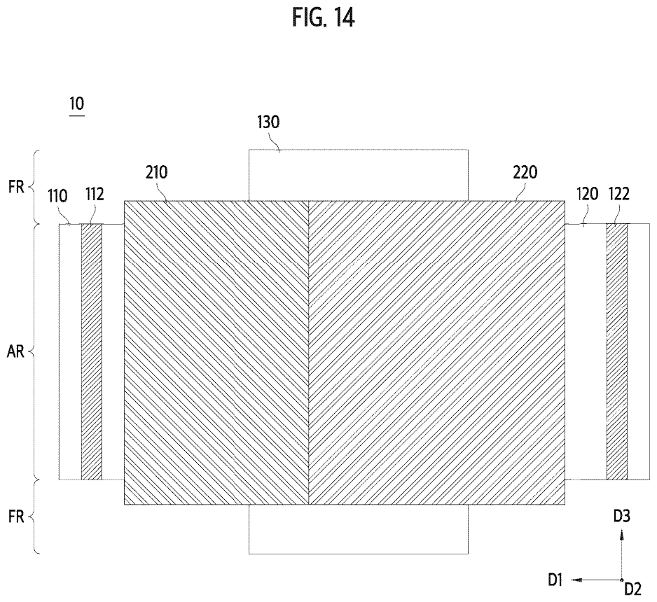

FIG. 10 is a layout of the semiconductor device 10 including the first field plate 210 in the planar form according to some example embodiments. FIG. 11 is a layout of the semiconductor device 10 including the first field plate 210 in the planar form and the second field plate 220 in the mesh form according to some example embodiments. FIG. 12 is a layout of the semiconductor device 10 including the second field plate 220 in the planar form according to some example embodiments. FIG. 13 is a layout of the semiconductor device 10 including the first field plate 210 in the mesh form and the second field plate 220 in the planar form according to some example embodiments. FIG. 14 is a layout of the semiconductor device 10 including the first field plate 210 and the second field plate 220 in the planar form according to some example embodiments. The semiconductor device 10 of FIGS. 10-14 may be same as or similar in some respects to the semiconductor device 10 of FIGS. 1-9, and therefore may be best understood with reference thereto where like numerals indicate like elements not described again in detail.

In some example embodiments, when viewed in the second direction D2, the first field plate 210 may overlap a portion of the first source/drain region 110 and a portion of the gate electrode 130, and there may be no through hole formed. Here, the first field plate 210 may have the planar form.

In some example embodiments, the second field plate 220 may overlap a portion of the second source/drain region 120 and a portion of the gate electrode 130 when viewed in the second direction D2, and there may be no through hole formed. Here, the second field plate 220 may have the planar form.

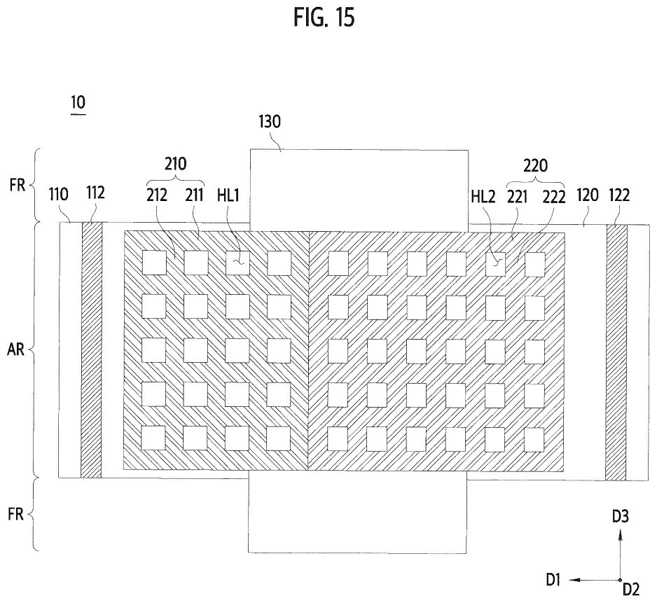

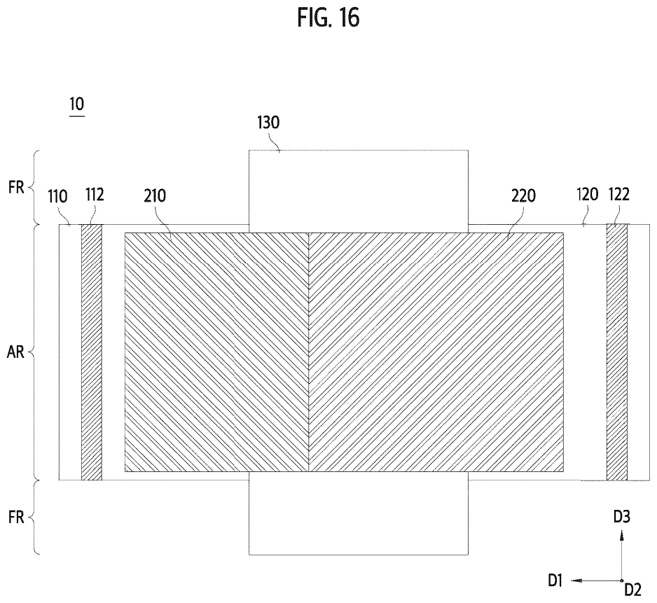

FIG. 15 is a layout of the semiconductor device 10 including the first field plate 210 and the second field plate 220 in the mesh form and the first field plate 210 and the second field plate 220 are disposed only on the active region AR, according to some example embodiments. FIG. 16 is a layout of the semiconductor device 10 including the first field plate 210 and the second field plate 220 in the planar form and the first field plate 210 and the second field plate 220 are disposed only on the active region AR, according to some example embodiments. The semiconductor device 10 of FIGS. 15 and 16 may be same as or similar in some respects to the semiconductor device 10 of FIGS. 1-14, and therefore may be best understood with reference thereto where like numerals indicate like elements not described again in detail.

In some example embodiments, when viewed in the second direction D2, at least one of the first field plate 210 and the second field plate 220 may overlap with the active region AR and may not overlap with the field region FR. In other words, at least one of the first field plate 210 and the second field plate 220 may only be disposed in the active region AR.

In some example embodiments, when viewed in the second direction D2, the first field plate 210 and the second field plate 220 may overlap with the active region AR and not overlap with the field region FR. In other words, the first field plate 210 and the second field plate 220 may only be disposed in the active region AR.

The example embodiments of the present disclosure are described with reference to the attached drawings. However, the present disclosure is not limited to the example embodiments, and the present disclosure can be manufactured in various other forms, and a person skilled in the art to which the present disclosure pertains will understand that the present disclosure can be implemented in other specific forms without changing its technical idea or essential features. Therefore, the example embodiments described above should be understood in all respects as illustrative and not limiting.

What is claimed is:

1. A semiconductor device comprising:
a substrate;
a gate electrode on the substrate;
a first source/drain region in the substrate;
a second source/drain region in the substrate and spaced apart from the first source/drain region, the gate electrode being between the first source/drain region and the second source/drain region in a first direction parallel to a surface of the substrate;
a first source/drain contact connected with the first source/drain region;
a second source/drain contact connected with the second source/drain region;
a gate contact connected with the gate electrode;
a first field plate connected with the gate contact, and comprising a first region at least partially overlapping with the first source/drain region when viewed in a second direction perpendicular to the surface of the substrate; and
a second field plate connected with the first field plate, and comprising a second region at least partially overlapping with the second source/drain region when viewed in the second direction,
wherein a distance between the second source/drain region and the second region in the second direction is greater than a distance between the first source/drain region and the first region in the second direction.

2. The semiconductor device of claim 1, wherein a distance between the first source/drain contact and the gate electrode in the first direction is different from a distance between the second source/drain contact and the gate electrode in the first direction.

3. The semiconductor device of claim 2, wherein the distance between the first source/drain contact and the gate electrode in the first direction is greater than the distance between the second source/drain contact and the gate electrode in the first direction.

4. The semiconductor device of claim 1, wherein a distance between the first source/drain contact and the gate electrode in the first direction is a same as a distance between the second source/drain contact and the gate electrode in the first direction.

5. The semiconductor device of claim 1, wherein
the first field plate further comprises a third region at least partially overlapping with the gate electrode when viewed in the second direction and connected with the first region, and
the second field plate further comprises a fourth region at least partially overlapping with the gate electrode when viewed in the second direction and connected with the second region.

6. The semiconductor device of claim 5, wherein
a distance between the substrate and the third region in the second direction is different from the distance between the first source/drain region and the first region in the second direction, and
a distance between the substrate and the fourth region in the second direction is different from the distance between the second source/drain region and the second region in the second region.

7. The semiconductor device of claim 5, wherein the third region comprises:
a 3-1 region that extends in a direction same as a direction in which the first region extends with respect to the gate contact; and
a 3-2 region that extends in a direction opposite to the direction in which the 3-1 region extends.

8. The semiconductor device of claim 5, wherein the fourth region comprises:
a 4-1 region that extends in a direction same as a direction in which the second region extends with respect to the gate contact; and
a 4-2 region that extends in a direction that is opposite to the direction in which the 4-1 region extends.

9. The semiconductor device of claim 1, wherein the first field plate and the second field plate are spaced apart from each other in the second direction.

10. The semiconductor device of claim 9, further comprising:
a connecting contact in a space between the first field plate and the second field plate, and connected with the first field plate and the second field plate.

11. The semiconductor device of claim 10, wherein the connecting contact at least partially overlaps a region of the gate contact when viewed in the second direction.

12. The semiconductor device of claim 1, wherein the first field plate and the second field plate contact each other in the second direction.

13. The semiconductor device of claim 1, wherein, when viewed in the second direction, the first field plate does not overlap with the first source/drain contact, and the second field plate does not overlap with the second source/drain contact.

14. The semiconductor device of claim 1, further comprising:
a gate insulating film between the gate electrode and the substrate, and overlapping at least a region of the gate electrode when viewed in the second direction.

15. A semiconductor device comprising:
a substrate;
an active region that comprises a first source/drain region in the substrate and a second source/drain region that is spaced apart from the first source/drain region in a first direction parallel to a surface of the substrate, the active region extending in the first direction;
a field region that does not overlap with the active region when viewed in a second direction perpendicular to the surface of the substrate;
a gate electrode between the first source/drain region and the second source/drain region on the substrate, the gate electrode extending in a third direction parallel to the surface of the substrate and intersecting with the first direction;
a first source/drain contact connected to the first source/drain region;
a second source/drain contact connected to the second source/drain region;
a gate contact connected to the gate electrode;
a first field plate connected to the gate contact, and comprising a first region at least partially overlapping with the first source/drain region when viewed in the second direction; and
a second field plate connected to the first field plate and comprising a second region at least partially overlapping with the second source/drain region when viewed in the second direction,
wherein a distance between the second source/drain region and the second region in the second direction is greater than a distance between the first source/drain region and the first region in the second direction.

16. The semiconductor device of claim 15, wherein
the first field plate is one of a plurality of first field plates, and
each first field plate of the plurality of first field plates extends in the first direction, and the plurality of first field plates are spaced apart from each other in the third direction.

17. The semiconductor device of claim 15, wherein the first field plate comprises:
one or more 1-1 field plates extending in the first direction; and
one or more 1-2 field plates extending in the third direction, wherein
the one or more 1-1 field plates and the one or more 1-2 field plates together define one or more first cross holes.

18. The semiconductor device of claim 15, wherein
the first field plate overlaps with at least a portion of the first source/drain region and at least a portion of the gate electrode when viewed in the second direction, and
the first field plate does not include a through hole.

19. The semiconductor device of claim 15, wherein, when viewed in the second direction, at least one of the first field plate and the second field plate overlaps with the active region, and does not overlap with the field region.

20. A semiconductor device comprising:
a substrate;
an active region that comprises a first source/drain region in the substrate and a second source/drain region spaced apart from the first source/drain region in a first direction parallel to a surface of the substrate, the active region extending in the first direction;
a field region that does not overlap with the active region when viewed in a second direction perpendicular to the surface of the substrate;
a gate electrode between the first source/drain region and the second source/drain region on the substrate, the gate electrode extending in a third direction parallel to the surface of the substrate and intersecting with the first direction;
a first source/drain contact connected to the first source/drain region;
a second source/drain contact connected to the second source/drain region;
a gate contact connected to the gate electrode;
a first field plate connected to the gate contact, and comprising a first region at least partially overlapping with the first source/drain region and a third region at least partially overlapping with the gate electrode and connected with the first region when viewed in the second direction; and
a second field plate connected to the first field plate, and comprising a second region at least partially overlapping with the second source/drain region and a fourth region at least partially overlapping with the gate electrode and connected with the second region when viewed in the second direction,
wherein the third region comprises a 3-1 region extending in a direction same as a direction in which the first region extends with respect to the gate contact, and a 3-2 region extending in a direction opposite to the direction in which the 3-1 region extends,
wherein the fourth region comprises a 4-1 region extending in a direction same as a direction in which the second region extends with respect to the gate contact, and a 4-2 region extending in a direction opposite to the direction in which the 4-1 region extends,
wherein a distance between the second source/drain region and the second region in the second direction is greater than a distance between the first source/drain region and the first region in the second direction, and
wherein a distance between the first source/drain contact and the gate electrode in the first direction is greater than a distance between the second source/drain contact and the gate electrode in the first direction.
